(19) United States
(12) Patent Application Publication
(10) Pub. No.: US 2023/0207346 A1
(43) Pub. Date: Jun. 29, 2023

(54) TEMPERATURE-CONTROL DEVICE, SYSTEM, AND METHOD FOR CONTROLLING THE TEMPERATURE OF A PROBER TABLE FOR SEMICONDUCTOR WAFERS AND/OR HYBRIDS

(71) Applicant: ATT Advanced Temperature Test Systems GmbH, Planegg (DE)

(72) Inventors: Markus Eibl, Planegg (DE); Thomas Lippert, Planegg (DE); Ferdinand Wimmer, Planegg (DE)

(21) Appl. No.: 17/925,956

(22) PCT Filed: Apr. 21, 2021
(86) PCT No.: PCT/EP2021/060290

§ 371 Date: Nov. 17, 2022

(30) Foreign Application Priority Data
May 18, 2020 (DE) 10 2020 002 962.0

(51) Int. Cl. H01L 21/67; G01R 31/28

(52) U.S. Cl. CPC H01L 21/67103; G01R 31/2831; F25B 9/04

(57) ABSTRACT

A temperature-control device (1) is provided for controlling the temperature of a prober table (110) for semiconductor wafers and/or hybrids. The device has a fluid inlet (10) for introducing a temperature-control fluid into the temperature-control device (1) and a first heat exchanger (20) for preliminary control of the temperature of the temperature-control fluid that is introduced. A second heat exchanger (30) is used to control the temperature of the temperature-control fluid. The temperature-controlled temperature-control fluid can be conducted to the prober table (110) through a prober temperature-control line (40). A return circuit (60) is configured, so that upon receiving a return switch signal, the return circuit (60) selectively either conducts a temperature-control fluid returned from the prober table (110) through the first heat exchanger (20) or allows the temperature control fluid to flow out bypassing the first heat exchanger (20).

The invention relates to temperature-regulating apparatuses, a system having a sampler stage and a temperature-regulating apparatus, and methods for temperature regulation of a sampler stage for semiconductor wafers and/or hybrids.

From the prior art, testing apparatuses and methods are known in which semiconductor wafers are tested in temperature ranges between −200° C. and +400° C. To do so, a semiconductor wafer is placed upon a sampler stage, which is cooled and/or heated to the respectively desired testing temperature. Such sampler stages are also called wafer samplers and/or chucks. For the temperature regulation, a temperature-regulating fluid is conducted to and/or through the sampler stage, which cools and/or heats the sampler stage to the desired testing temperature. In principle, methods with liquid temperature-regulating fluids as well as with gaseous temperature-regulating fluids are known.

In the document EP 1 495 486 B3, an embodiment of a temperature-regulating apparatus is described, in which a temperature-regulating fluid is first used for temperature regulation of a sampler stage. Subsequently, the temperature-regulating fluid is conducted from the sampler stage back into the temperature-regulating apparatus and from there through a heat exchanger, in which it is used for the temperature regulation of the freshly introduced temperature-regulating fluid. This has the advantage that the “recycled” fed back temperature-regulating fluid can be used once more for temperature regulation of at least a portion of the temperature-regulating fluid freshly introduced into the temperature-regulating apparatus. As a result, for example, the total cooling energy needed for cooling down the temperature-regulating fluid can be reduced.

The known methods and/or temperature-regulating apparatuses have the disadvantage that they still require a large amount of energy for adjusting the testing temperatures of the sampler stage.

The problem addressed by the invention is to provide a possibility for temperature-regulating sampler stages in an energy-efficient manner. A further problem addressed by the invention can be to provide a possibility for faster adjustment of testing temperatures of the sampler stage.

This problem is solved by the subject-matters of the independent claims. Preferred embodiments are the subject-matters of the dependent claims.

A first aspect relates to a temperature-regulating apparatus for the temperature regulation of a sampler stage for semiconductor wafers and/or hybrids, having a fluid inlet for introducing a temperature-regulating fluid into the temperature-regulating apparatus. The temperature-regulating apparatus comprises a first heat exchanger for the temperature pre-regulation of the introduced temperature-regulating fluid and a second heat exchanger for the temperature regulation of the temperature-regulating fluid. The temperature regulated temperature-regulating fluid can be conducted to the sampler stage through a sampler temperature-regulating line. In response to a feedback switch signal, a feedback circuit optionally either conducts a temperature-regulating fluid fed back from the sampler stage through the first heat exchanger or allows it to flow out while bypassing the heat exchanger.

The temperature-regulating apparatus can be configured as a so-called chiller, which is configured and provided so as to be connected to the sampler stage at least via the sampler temperature-regulating line. Such a sampler stage for the testing of semiconductor wafers and/or hybrids is also referred to as a chuck and is typically arranged in an at least partially closed sampler container. The temperature-regulating apparatus can thus be configured as part of a sampler system, which can comprise both the temperature-regulating apparatus as well as the sampler stage with or without the sampler container.

The temperature-regulating apparatus can furthermore comprise a control unit and/or can be connected to a control unit. The control unit can comprise at least one switch valve and or one processor, on which software programs can be executed.

The fluid inlet serves to introduce the temperature-regulating fluid into the temperature-regulating apparatus, e.g. into a housing of the temperature-regulating apparatus, through the housing wall of which the fluid inlet can be configured.

A liquid and or gaseous fluid can be used as the temperature-regulating fluid. Preferably, a gaseous fluid such as dry air can be used as the temperature-regulating fluid, wherein the temperature-regulating apparatus is configured as an air-cooled temperature-regulating apparatus.

The temperature-regulating apparatus comprises at least two heat exchangers, namely the first heat exchanger for the temperature pre-regulation of the introduced temperature-regulating fluid and the second heat exchanger for the actual temperature regulation of the temperature-regulating fluid. The temperature-regulating fluid can be conducted from the fluid inlet into the first heat exchanger and from the first heat exchanger to the second heat exchanger. From the second heat exchanger, it can be conducted to the sampler temperature-regulating line.

The temperature regulation of the supplied temperature-regulating fluid can occur in a plurality of steps and/or stages. During the temperature pre-regulation in the first heat exchanger, the temperature-regulating fluid does not yet need to be brought to its target temperature that is desired for the temperature regulation, i.e. not yet to the testing temperature of the sampler stage. However, during the temperature pre-regulation, the temperature of the supplied temperature-regulating fluid can be changed from its provisional temperature, i.e. for example approximately room temperature, to the desired target temperature of the temperature-regulating fluid. It is only in the second heat exchanger that the temperature-regulating fluid is temperature-regulated to its desired target temperature. As the target temperature of the temperature-regulating fluid, for example, the currently set testing temperature of the sampler stage can be used. During the cooling of the sampler stage, the temperature-regulating fluid can be temperature-regulated at least temporarily to a minimum possible target temperature, which can be significantly colder than the actual testing temperature, in order to adjust the sampler stage as quickly as possible to its new testing temperature.

The first heat exchanger is configured for the temperature pre-regulation of the introduced, for example fresh, temperature-regulating fluid. In the first heat exchanger, a heat exchange can take place between the freshly introduced temperature-regulating fluid and the fed back temperature-regulating fluid. As a result of this heat exchange, the freshly introduced temperature-regulating fluid is temperature pre-regulated by the fed back temperature-regulating fluid, which can still be approximately the desired testing temperature.

The feedback circuit can switch the temperature-regulating apparatus into a feedback operating state, in which the temperature-regulating fluid which is fed back and/or conducted back is conducted through the first heat exchanger. The feedback operating state can be used, for example in a cooling mode in which the sampler stage is to be cooled down to a lower testing temperature, for example −40° C., in order to pre-cool the freshly introduced temperature-regulating fluid in the first heat exchanger by means of the temperature-regulating fluid fed back from the sampler stage. Thus, the fed back temperature-regulating fluid could still have a coldness of, for example, −30° C., with which the fresh temperature-regulating fluid, which is introduced for example at approximately room temperature, can be well pre-cooled. At any rate, with this use of the coldness of the fed back temperature-regulating fluid, the freshly introduced temperature-regulating fluid could already be pre-cooled by a few degrees, for example to a temperature below 0° C. Subsequently, the fresh temperature-regulating fluid can be cooled down in the second heat exchanger to its target temperature, for example to the predetermined testing temperature of −40° C.

On the one hand, the temperature pre-regulation allows the target temperature to be achieved with as much energy saving as possible, in that the heat and/or coldness content of the fed back temperature-regulating fluid is sensibly used. On the other hand, the temperature pre-regulation can enable an achievement of extreme temperatures in the first place. Thus, for example, the use of the fed back temperature-regulating fluid for the temperature pre-regulation of the fresh temperature-regulating fluid can enable the achievement of a very cold temperature in the first place.

While the use of the fed back temperature-regulating fluid for the temperature pre-regulation of the fresh temperature-regulating fluid can thus be sensible in a plurality of operating states of the temperature-regulating apparatus and can contribute to energy efficiency, in other operating states this can have negative effects on the energy usage and can lead, for example, to a relatively high energy consumption.

If, for example, the sampler stage is cooled down from a relatively high testing temperature (e.g. from several hundred degrees Celsius) to a temperature close to room temperature, then a temperature pre-regulation with the hot fed back temperature-regulating fluid is undesirable. This is because the temperature pre-regulation would first preheat the temperature-regulating fluid that has been freshly introduced at, for example, approximately room temperature, to a temperature that is too high before it must be cooled back down to the testing temperature in the second heat exchanger. For this purpose, a high cooling capacity and thus a large amount of cooling energy is required.

In order to improve the energy usage, the temperature-regulating apparatus comprises the feedback circuit. The feedback circuit receives the feedback switch signal, for example, from the control unit. The feedback switch signal can be dependent on the respectively desired operating state of the temperature-regulating apparatus.

If, for example, the sampler stage is to render a strong cooling capacity and is not preheated, then the feedback circuit can conduct the fed back temperature-regulating fluid through the first heat exchanger, where it can be used for the temperature pre-regulation of the freshly introduced temperature-regulating fluid. The feedback circuit is then in the feedback operating state.

In order to cool the sampler stage from a strongly heated state, the feedback circuit can redirect the fed back temperature-regulating fluid in response to a corresponding feedback switch signal. In such a state, the feedback circuit can allow the fed back fluid to flow out, for example. In any case, in this state, the feedback circuit no longer conducts the fed back temperature-regulating fluid through the first heat exchanger for the temperature pre-regulation of the fresh fluid. The feedback circuit is then in the outflow operating state.

The feedback circuit is thus reversibly switchable between at least two states, namely between the feedback operating state and the outflow operating state. In the feedback operating state of the feedback circuit, the fed back temperature-regulating fluid is conducted through the first heat exchanger, and in the outflow operating state of the feedback circuit, the fed back temperature-regulating fluid is allowed to flow out while bypassing the first heat exchanger. For example, it can then be simply discharged into the environment without being conducted through the first heat exchanger.

Due to the feedback circuit, in particular in the case of strong cooling of the sampler stage, cooling energy can be saved, because the fed back temperature-regulating fluid no longer unnecessarily heats the fresh temperature-regulating fluid in the first heat exchanger when the predetermined testing temperature does not require this. The feedback circuit can thus save cooling energy and reduce the operating costs of the temperature-regulating apparatus. Furthermore, the operating noise caused by the temperature-regulating apparatus can also be reduced, in that, at least in some operating states, the cooling does not have to be as strong in the second heat exchanger. Furthermore, due to the energy savings, operating costs can be saved, in particular operating costs such as power and/or maintenance costs caused by wear of a cooling apparatus coupled to the second heat exchanger.

After the temperature pre-regulation in the first heat exchanger, the fed back temperature-regulating fluid can either be allowed to flow out to the environment and/or it can be allowed to flow out in the sampler container in order to condition the ambient air there. The same is true for the outflow of the fed back temperature-regulating fluid while bypassing the first heat exchanger.

In some operating states and/or operating transitions, the possibility of allowing the fed back temperature-regulating fluid to flow out while bypassing the first heat exchanger enables the testing temperature on the sampler stage to be set significantly faster than with the use of the fed back heat content. This is true, in particular, when cooling off the sampler stage from a heated state of, for example, several hundred degrees Celsius to a moderate temperature around room temperature and/or in the negative Celsius range.

According to one embodiment, in a feedback operating state of the temperature-regulating apparatus, the fed back temperature-regulating fluid temperature pre-regulates the introduced temperature-regulating fluid in the first heat exchanger when it is conducted by the feedback circuit through the first heat exchanger. Here, the feedback operating state of the temperature-regulating apparatus can be an operating state in which the temperature changes in comparatively small steps, for example in steps of maximum 40K, preferably maximum 25K, particularly preferably maximum 10K. In general, the cooling operating state of the temperature-regulating apparatus can be a state in which the freshly introduced temperature-regulating fluid is temperature pre-regulated to its testing temperature in the first heat exchanger as well as in the second heat exchanger. Here, the testing temperature can be, for example, within a range between a minimum adjustable temperature of the temperature-regulating apparatus and a lower threshold temperature. The minimum adjustable testing temperature can be the lowest testing temperature that is achievable by the temperature-regulating apparatus, for example −40° C. or −55° C. or −200° C. The lower threshold temperature can be close to room temperature, i.e. for example it can lie within a range from approximately 10° C. to approximately 35° C. In this temperature range from the minimum achievable testing temperature to the lower threshold temperature, the temperature-regulating apparatus can typically be operated in the feedback operating state.

According to one embodiment, after flowing through the first heat exchanger, the fed back temperature-regulating fluid is allowed to flow out via an outflow outlet. Here, in outflow line can be provided, connects the first heat exchanger to the outflow outlet. Via the outflow outlet, the fed back temperature-regulating fluid can be allowed to flow out, for example into the environment, and/or can be at least partially used for conditioning the sampler container.

According to one embodiment, in an outflow operating state of the temperature-regulating apparatus, the feedback circuit allows the temperature-regulating fluid fed back from the sampler stage to flow out while bypassing the first heat exchanger when the sampler stage is cooled off from a heated state. In the outflow operating state, the fed back temperature-regulating fluid is thus no longer used for the temperature pre-regulation of the introduced fresh temperature-regulating fluid. As a result, the cooling energy required in the outflow operating state at the second heat exchanger can be reduced.

In general, the fed back temperature-regulating fluid can be allowed to flow out while bypassing the first heat exchanger when a temperature pre-regulation is counterproductive to the temperature regulation, i.e. for example the temperature of the fed back temperature-regulating fluid deviates too greatly from the target temperature to which the introduced temperature-regulating fluid is to be temperature-regulated.

Furthermore, there is the possibility to allow the fed back temperature-regulating fluid to flow out while bypassing the first heat exchanger when the target temperature to be achieved is closer to the provisional or introduction temperature (i.e., for example, approximately room temperature) of the freshly introduced temperature-regulating fluid than to the feedback temperature of the fed back temperature-regulating fluid. Here, with a view to the cooling capacity to be expended, it can almost always the worthwhile to omit the temperature pre-regulation in the first heat exchanger.

According to one embodiment, in an outflow operating state of the temperature-regulating apparatus, the feedback circuit allows the temperature-regulating fluid fed back from the sampler stage to flow out while bypassing the first heat exchanger when the sampler stage is cooled off from a first temperature to a second temperature that is more than 50K lower than the first temperature. The temperature-regulating apparatus is put into the outflow operating state when the second temperature, as the testing temperature of the fresh temperature-regulating fluid, deviates by more than approximately 50K, i.e. for example by at least approximately 100K or approximately 200K, from the first temperature, i.e. the current actual temperature of the sampler stage. This can also lead to savings of the cooling capacity to be expended in the second heat exchanger.

According to one embodiment, upon cooling of the sampler stage in an outflow operating state of the temperature-regulating apparatus, the feedback circuit allows the temperature-regulating fluid fed back from the sampler stage to flow out while bypassing the first heat exchanger until a temperature of the sampler stage falls below a sampler stage threshold temperature within a range of approximately 20° C. to approximately 40° C. Preferably, the sampler stage threshold temperature is somewhat greater than the room temperature and/or the provisional temperature of the temperature-regulating fluid and is, for example, approximately 30° C. If the temperature of the sampler stage falls below the sampler stage threshold temperature, then the temperature-regulating apparatus can be switched into the feedback operating state.

According to one embodiment, in a feedback operating state of the temperature-regulating apparatus, the feedback circuit conducts the temperature-regulating fluid fed back from the sampler stage through the first heat exchanger when the sampler stage is temperature-regulated to a temperature below a feedback threshold temperature. Here, the feedback threshold temperature can lie within a range from approximately 10° C. to approximately 40° C., in particular within a range from approximately 20° C. to approximately 35° C. With such a testing temperature, it can usually be sensible to operate the temperature-regulating apparatus in the feedback operating state in order to thus use the relative coldness of the fed back temperature-regulating fluid for the temperature pre-regulation of the freshly introduced temperature-regulating fluid.

In general, in addition to a line bifurcation, the feedback circuit can comprise an outlet valve and/or an over-pressure valve and or a switch valve, through whose switch position(s) it can be adjusted whether the fed back temperature-regulating fluid is allowed to flow out or whether it is conducted through the first heat exchanger.

A second aspect relates to a temperature-regulating apparatus for the temperature regulation of a sampler stage for semiconductor wafers and/or hybrids. This can be, in particular, a temperature-regulating apparatus according to the first aspect. The temperature-regulating apparatus comprises a fluid inlet for introducing a temperature-regulating fluid into the temperature-regulating apparatus and at least one heat exchanger for the temperature regulation of the temperature-regulating fluid. A cooling booster is likewise provided for the temperature regulation of the temperature-regulating fluids. The temperature-regulating apparatus comprises a sampler temperature-regulating line, through which the temperature-regulated temperature-regulating fluid can be conducted to the sampler stage. In response to an introduction switch signal, an inlet fluid circuit optionally conducts the introduced temperature-regulating fluid into the sampler stage temperature-regulating line either through the at least one heat exchanger or through cooling booster.

In particular, the temperature-regulating apparatus can be configured as a temperature-regulating apparatus according to the first aspect. For this reason, the comments regarding individual features of the temperature-regulating apparatus according to the first aspect also relate to the temperature-regulating apparatus according to the second aspect, and vice versa. Thus, in particular, the fluid inlet, the temperature-regulating fluid, the sampler temperature-regulating line, etc., can be similar or identical. The at least one heat exchanger of the temperature-regulating apparatus according to the second aspect can, for example, be the second or first heat exchanger of the previously described temperature-regulating apparatus according to the first aspect.

By contrast to and/or in addition to the elements of the temperature-regulating apparatus according to the first aspect, the temperature-regulating apparatus according to the second aspect comprises at least the cooling booster and the inlet fluid circuit. The inlet fluid circuit receives the introduction switch signal, for example from a control unit, with which the inlet fluid circuit is controlled and/or regulated, so that at least a majority of the introduced temperature-regulating fluid is conducted either through the at least one heat exchanger or through the cooling booster.

Depending on the selected and/or switched conduction path of the introduced temperature-regulating fluid, there arise different operating modes of the temperature-regulating apparatus. In the heat exchanger mode, the introduced temperature-regulating fluid is conducted through the at least one heat exchanger. In the booster mode, the introduced temperature-regulating fluid is instead temperature-regulated in the cooling booster. Depending on the desired testing temperature of the sampler stage, one of the two modes can be more favorable in terms of energy.

For example, in a low temperature range, it may be necessary to temperature-regulate the introduced temperature-regulating fluid in the at least one heat exchanger, because only in this way can the low testing temperature be achieved. However, in a moderate temperature range, it may be sensible to switch off the heat exchanger with the associated cooling apparatus and instead adjust the testing temperature only with the cooling booster, which requires less operating capacity. The booster mode can thus be sensible, for example, at lower positive temperatures around room temperature. For example, the cooling booster may require significantly less operating energy than a cooling apparatus for the second heat exchanger, because this cooling apparatus may require a cooling aggregate and/or a condenser.

The temperature-regulating apparatus combines the advantages of using a cooling booster, which requires comparatively little operating energy, with the possibility of being able to cool down the temperature-regulating fluid in the (e.g. second) heat exchanger to a very low temperature, which cannot be achieved by the cooling booster alone. The inlet fluid circuit can be controlled as intelligently as possible in order to enable the greatest possible energy savings in operation.

Here, a branching and/or the convergence can be provided, at which an outlet line from the at least one heat exchanger is coupled to an outlet line from the cooling booster in such a way that the temperature-regulated temperature-regulating fluid can be conducted into the sampler temperature-regulating line either from the heat exchanger or from the cooling booster. For this purpose, a shuttle valve and/or an “OR” valve can be used.

According to one embodiment, in a heat exchanger operating mode of the temperature-regulating apparatus, the inlet fluid circuit conducts the introduced temperature-regulating fluid through the at least one heat exchanger into the sampler temperature-regulating line when the sampler stage is cooled off from a heated state. Here, the heat exchanger mode is the operating mode of the temperature-regulating apparatus in which the inlet fluid circuit conducts the freshly introduced temperature-regulating fluid through the at least one heat exchanger. This can be advantageous, for example, in an outflow operating state described in conjunction with the first aspect, in which the sampler stage is to be quickly cooled off from a heated state.

According to one embodiment, in a heat exchanger operating mode of the temperature-regulating apparatus, the inlet fluid circuit conducts the introduced temperature-regulating fluid through the at least one heat exchanger into the sampler temperature-regulating line when the sampler stage is temperature-regulated to a temperature below a lower threshold temperature lying within a range of approximately 10° C. to approximately 25° C. Here, the temperature-regulating apparatus can be configured such that it can always be operated in the heat exchanger mode when the sampler stage is to be temperature-regulated to a target temperature below the lower threshold temperature.

According to one embodiment, in a booster operating mode of the temperature-regulating apparatus, the inlet fluid circuit conducts the introduced temperature-regulating fluid through the cooler booster into the sampler temperature-regulating line when the sampler stage is temperature-regulated to a temperature above an upper threshold temperature lying within a range of approximately 10° C. to approximately 25° C. and below a lower threshold temperature lying within a range of approximately 40° C. to approximately 70° C. In the booster mode, the temperature-regulating apparatus normally requires less operating energy than in the heat exchanger mode. For this reason, it is sensible in terms of energy to enable the operation of the temperature-regulating apparatus in the booster mode. In the booster mode, the cooling apparatus for cooling down the at least one heat exchanger can be switched off, which can reduce the operating noise of the temperature-regulating apparatus. The booster mode is suitable in particular for an operation of the temperature-regulating apparatus in which the sampler stage is to be temperature-regulated to a testing temperature in a moderate temperature range, for example around room temperature. Here, the moderate temperature range can range from the lower threshold temperature up to approximately the upper threshold temperature. In one exemplary embodiment, the lower threshold temperature can be approximately 15° C. In one exemplary embodiment, the upper threshold temperature can be approximately 15° C. or approximately 60° C.

According to one embodiment, the cooling booster comprises a vortex tube in which the introduced temperature-regulating fluid is divided into a warm and a cold flow portion, of which only the cold flow portion is conducted into the sampler temperature-regulating line. The principle of the vortex tube is known to the person skilled in the art. In the vortex tube, the introduced temperature-regulating fluid is swirled and/or set into rotation, such that it is divided into a warm and a cold portion. The warm and cold portions of the temperature-regulating fluid are conducted out of the vortex tube and/or the cooling booster through different outlets. Only the cold portion of the temperature-regulating fluid is further used and provided for the temperature regulation of the sampler stage. This cold portion is conducted into the sampler temperature-regulating line.

According to one embodiment, the inlet fluid circuit comprises a switch valve through which the introduced temperature-regulating fluid is optionally conducted to either the at least one heat exchanger or the cooling booster as a function of the switch position of the switch valve. Here, the switch valve is arranged within a line for the introduced temperature-regulating fluid such that its position diverts the temperature-regulating fluid in a direction either to the at least one heat exchanger or to the cooling booster. Here, the switch valve does not have to be directly connected to the cooling booster and/or the heat exchanger. For example, before the at least one heat exchanger for temperature regulation, it can be conducted into another (e.g. first) heat exchanger for temperature pre-regulation. Moreover, at least one further valve and/or one circuit and/or one further (e.g. first) heat exchanger can be provided between the switch valve and the cooling booster.

A third aspect relates to a system having a sampler stage and a temperature-regulating apparatus according to the first and/or second aspect connected thereto at least via its sampler temperature-regulating line. The system can be configured as a sampler system and can comprise the sampler stage in an at least partially closed sampler container. Cleanroom conditions can be present in the sampler container. The system can be used in order to test semiconductor wafers and/or hybrids under controlled, adjustable conditions such as, for example, specifiable testing temperatures. Alternatively, the system can also be configured without the sampler container, and the temperature-regulating apparatus can comprise the sampler stage as well as any required lines.

A fourth aspect relates to a method for temperature regulation of a sampler stage for semiconductor wafers and/or hybrids, having the following steps:
introducing a temperature-regulating fluid into a first heat exchanger for temperature pre-regulation of the introduced temperature-regulating fluid;
conducting the temperature-regulating fluid from the first heat exchanger into a second heat exchanger for temperature regulation of the temperature-regulating fluid;
conducting the temperature-regulated temperature-regulating fluid to the sampler stage; and
providing a feedback switch signal for controlling and/or adjusting a feedback circuit, wherein, in response to a feedback switch signal, a temperature-regulating fluid fed back from the sampler stage is optionally either conducted through the first heat exchanger or is allowed to flow out while bypassing the first heat exchanger.

In particular, the method can be performed while using a temperature-regulating apparatus according to the first aspect. For this reason, all comments regarding the temperature-regulating apparatus according to the first aspect also relate to the method according to the fourth aspect, and vice versa. In the method, the freshly introduced temperature-regulating fluid can be temperature pre-regulated in the first heat exchanger and can be temperature pre-regulated, for example to its target temperature, in the second heat exchanger. The feedback circuit allows the fed back temperature-regulating fluid to be used for the temperature pre-regulation in the first heat exchanger precisely when this is sensible, for example in terms of energy, and reduces a cooling capacity required in the second heat exchanger. In all other operating states, the fed back temperature-regulating fluid can be allowed to flow out while bypassing the first heat exchanger.

In a further development of the method, at least one of the following steps is carried out:
allowing the outflow of the temperature-regulating fluid fed back from the sampler stage while bypassing the first heat exchanger when the sampler stage is cooled off from a heated state; and/or
conducting the temperature-regulating fluid fed back from the sampler stage through the first heat exchanger when the sampler stage is temperature-regulated to a temperature below a feedback threshold temperature.

The fed back temperature-regulating fluid can be allowed to flow out while bypassing the first heat exchanger when an outflow operating state is desired, i.e., for example, the sampler stage is cooled off from a first temperature to a second temperature, which can be, for example, at least approximately 50K lower than the first temperature. The feedback threshold temperature below which the fed back temperature-regulating fluid is conducted through the first heat exchanger can be within a range of approximately 20° C. to approximately 35° C., in particular approximately 30° C. and or room temperature.

A fifth aspect relates to a method for temperature regulation of a sampler stage for semiconductor wafers and/or hybrids, which can be in particular a supplement to the previously described method according to the fourth aspect, having the following steps:
introducing a temperature-regulating fluid into at least one heat exchanger for temperature regulation of the temperature-regulating fluid;
introducing the temperature-regulating fluid into a cooling booster for temperature regulation of the temperature-regulating fluid;
conducting the temperature-regulated temperature-regulating fluid to the sampler stage; and
providing an introduction switch signal for controlling and/or adjusting an inlet fluid circuit, wherein, in response to an introduction switch signal, the introduced temperature-regulating fluid is optionally conducted to the sampler stage either through the at least one heat exchanger or through the cooling booster.

In particular, the method can be performed by means of the temperature-regulating apparatus according to the second aspect. For this reason, all comments regarding the temperature-regulating apparatus according to the second aspect also relate to the method according to the fifth aspect, and vice versa. The method steps do not necessarily have to be performed in the stated sequence. Depending on the operating mode, the introduced temperature-regulating fluid can be conducted either through the at least one heat exchanger or through the cooling booster, in order to temperature-regulate the temperature-regulating fluid. During a testing cycle, the heat exchanger mode and the booster mode can be used with differing frequency.

According to one embodiment, at least one of the following steps can be performed in the method:
conducting the introduced temperature-regulating fluid through the at least one heat exchanger to the sampler stage when the sampler stage is temperature-regulated to a temperature below a lower threshold temperature lying within a range of approximately 10° C. to approximately 25° C.;
conducting the introduced temperature-regulating fluid through the cooler booster to the sampler stage when the sampler stage is temperature-regulated to a temperature above an upper threshold temperature lying within a range of approximately 10° C. to approximately 25° C. and below a lower threshold temperature lying within a range of approximately 40° C. to approximately 70° C.;
switching off a cooling apparatus used for temperature regulation within the heat exchanger when the introduced temperature-regulating fluid is conducted through the cooling booster to the sampler stage; and/or
switching off a cooling apparatus used for temperature regulation within the heat exchanger and/or switching off the cooling booster when the sampler stage is temperature-regulated to a temperature above the upper threshold temperature lying within a range of approximately 40° C. to approximately 70° C.

In a heat exchanger mode, the introduced temperature-regulating fluid can be conducted to the sampling stage through the heat exchanger, wherein it is also temperature-regulated in the heat exchanger. In a booster mode, the temperature-regulating fluid is conducted through the cooling booster and temperature regulated there before it is conducted to the sampler stage. The heat exchanger mode can always be used, for example, when the sampler stage is to be temperature-regulated to a temperature below the lower threshold temperature. The booster mode can be used in a moderate temperature range, which can include target temperatures from the lower threshold temperature to the upper threshold temperature.

If the sampler stage is to be temperature-regulated to a testing temperature above the upper threshold temperature, then the heat exchanger and/or the cooling booster can at least be switched off or placed into standby mode, because such testing temperatures can be set by a radiator at the sampler stage. This means that the sampler system and/or temperature-regulating apparatus can then be operated in a heating operating state. In this heating operating state, energy and costs can be saved by switching off and/or turning down a cooling apparatus used for temperature regulation in the heat exchanger and/or the cooling booster. Even when the introduced temperature-regulating fluid is temperature-regulated in the cooling booster, i.e. when the temperature-regulating apparatus is operated in the booster mode, the at least one heat exchanger can be switched off and/or placed into standby mode in order to thus reduce the total required energy.

Within the scope of this invention, the terms “substantially” and/or “approximately” can be used such that they indicate a deviation of up to 5% from a number following the term and a deviation of up to 5° from a direction and/or an angle following the term.

The term “testing temperature” can refer to a temperature that the sampler stage is to have in order to test the semiconductor wafers. During a testing cycle, the sampler stage can be set to various testing temperatures one after the other, in order to thus test the semiconductor wafer arranged on the sampler stage at various testing temperatures.

The term “target temperature” can refer to a temperature to which the temperature-regulating fluid is temperature-regulated and/or set in the temperature-regulating apparatus in order to bring the sampler stage to its testing temperature. The temperature regulation of the temperature-regulating fluid can take place, for example, in the second heat exchanger or in the cooling booster of the temperature-regulating apparatus. The target temperature can deviate from or be equal to the testing temperature.

In the following, the invention is further described on the basis of exemplary embodiments shown in the figures. For this purpose, the same or similar reference numerals refer to the same or similar features of the embodiments. Individual features shown in the figures can be implemented in other exemplary embodiments. The following are shown:

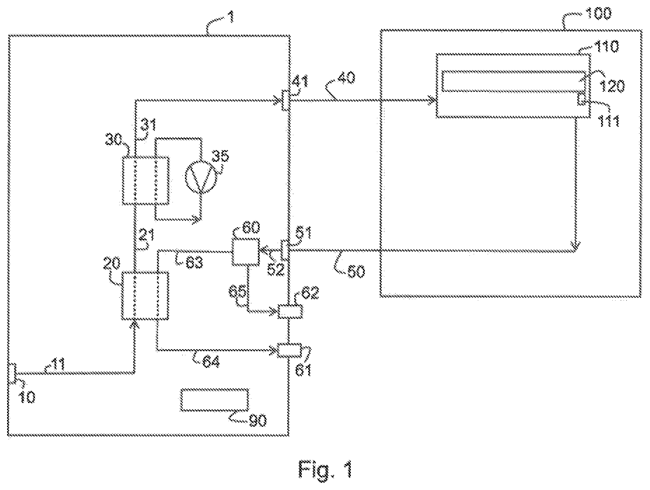

FIG. 1 a schematic outline of a sampler system having a temperature-regulating apparatus with a feedback circuit;

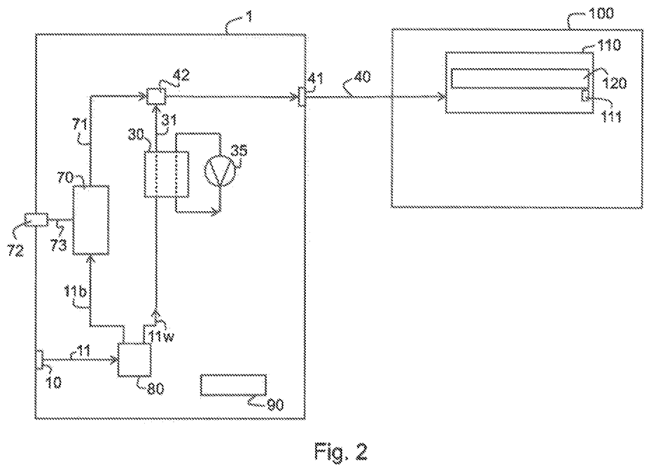

FIG. 2 a schematic outline of a sampler system having a temperature-regulating apparatus with an inlet fluid circuit;

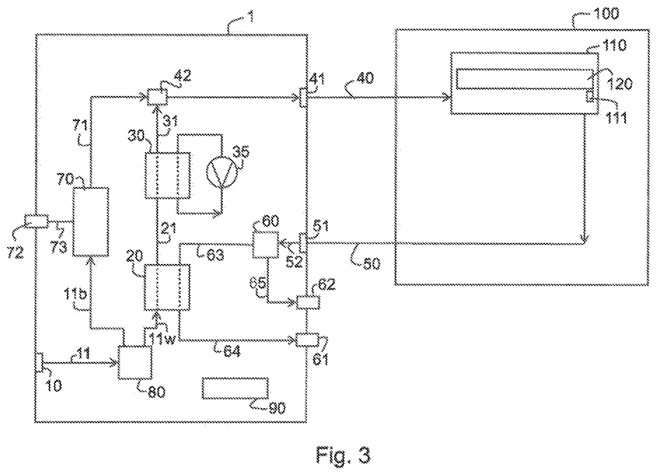

FIG. 3 a schematic outline of a sampler system having a temperature-regulating apparatus with a feedback circuit and an inlet fluid circuit; and

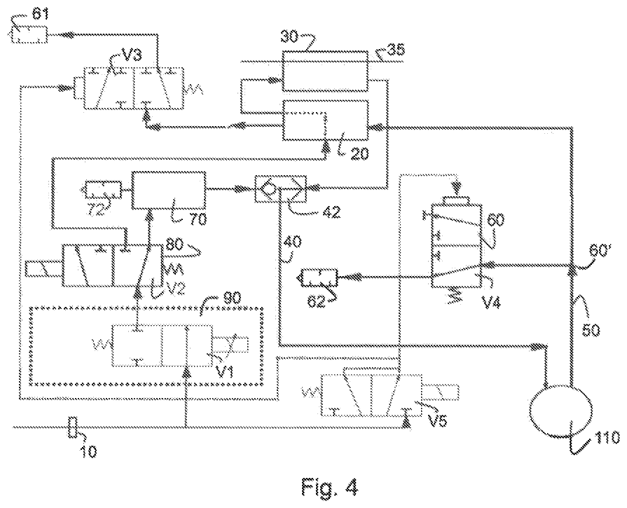

FIG. 4 a schematic circuit diagram of a sampler system having a feedback circuit and an inlet fluid circuit;

FIG. 1 shows a schematic outline of the sampler system having a temperature-regulating apparatus 1 and a sampler container 100. The sampler container 100 can be configured as a substantially closed space, in which a sampler stage 110 is arranged. The sampler stage 110 is also referred to as a chuck. For the temperature monitoring, a temperature sensor 111 can be arranged in the sampler stage 110. Furthermore, a radiator 120 can be arranged in the sampler stage 110 in order to condition the sampler stage 110 to testing temperatures above room temperature, for example to testing temperatures in the positive three-digit Celsius range.

The temperature-regulating apparatus 1 can be configured as a component that is separate from the sampler container 100 and can comprise, for example, a housing in which a plurality of design elements are arranged. The temperature-regulating apparatus 1 is also referred to as a chiller. A sampler system having a temperature-regulating apparatus 1 and a sampler stage 110 is also referred to as a chuck system.

The temperature-regulating apparatus 1 can comprise a control unit 90, which, as shown, can be arranged so as to be integrated in the housing of the temperature-regulating apparatus 1. Alternatively, the control unit 90 can be provided as a separate component, which can be connected to the temperature-regulating apparatus 1, for example electrically and/or via fluid lines. The control unit 90 can furthermore be connected electrically to the elements of the sampler system, in particular to the temperature sensor 111, the radiator 120, a feedback circuit 60, valves, and/or a cooling apparatus 35.

The temperature-regulating apparatus 1 comprises a fluid inlet 10 for freshly introduced temperature-regulating fluid. The fluid inlet 10 can be supplied, for example, with dry air, which can be introduced into the temperature-regulating apparatus 1 at approximately room temperature. In principle, a different temperature-regulating fluid than air can be used, for example another gas mixture and/or a liquid fluid. However, the temperature-regulating apparatus 1 is preferably configured as an air-cooling apparatus, which performs the temperature regulation of the sampler stage 110 with a mixture of air that is as dry as possible.

The temperature-regulating apparatus 1 further comprises a first heat exchanger 20 and the second heat exchanger 30. The temperature-regulating fluid freshly introduced via the fluid inlet 10 can first be conducted via an inlet line 11 through the first heat exchanger 20, in which it can be temperature pre-regulated. From there, it can be conducted through a heat exchanger connection line 21 to and then through the second heat exchanger 30 and from there through a heat exchanger outlet line 31 to a fluid outlet 41. Before the fluid outlet 41, for example in the heat exchanger outlet line 31, a fluid temperature sensor can be arranged, which checks the temperature of the temperature-regulated temperature-regulating fluid and is connected to and/or communicates with the control unit 90. The fluid temperature sensor can be used for expanded monitoring and/or control and/or regulation of the various operating states of the cooling apparatus 35, the temperature-regulating apparatus 1, and/or the sampler system. Alternatively, the fluid temperature sensor can also be arranged behind the fluid outlet in the sampler temperature-regulating line 40.

While passing through the first heat exchanger 20, the freshly introduced temperature-regulating fluid can be temperature pre-regulated. Depending on the operating state of the temperature-regulating apparatus 1, the freshly introduced temperature-regulating fluid can also pass through the first heat exchanger 20 without a temperature pre-regulation, i.e. at a nearly unchanged temperature.

The second heat exchanger 30 serves to adjust the desired target temperature of the temperature-regulating fluid. In the second heat exchanger 30, there is a heat exchange with a cooling fluid, which is cooled in the cooling apparatus 35. The cooling apparatus 35 can comprise one or more cooling aggregates, condensers, and/or similar cooling devices in order to cool the cooling fluid. The cooling apparatus 35 provides a majority of the cooling capacity to be expended and can furthermore be responsible for a majority of the operating noise. For this reason, the temperature-regulating apparatus 1 uses the cooling apparatus 35, to the extent possible, only when its cooling capacity is absolutely necessary. In all other operating states of the temperature-regulating apparatus 1, the cooling apparatus 35 is either switched off or placed into standby mode, to the extent possible, in order to save energy as well as reduce operating noise.

From the fluid outlet 41, the temperature-regulating fluid that has been temperature-regulated to its target temperature is conducted via a sampler temperature-regulating line 40 to the sampler stage 110. In the sampler stage 110, the temperature-regulated temperature-regulating fluid serves to set the desired testing temperature of the sampler stage 110. A testing temperature in the negative Celsius range and/or below room temperature can be set, for example, solely by using the coldness of the temperature-regulating fluid. In a temperature range significantly above the room temperature, the testing temperature of the sampler stage 110 can be set solely by the radiator 120.

To check the current actual temperature of the sampler stage 110, the temperature sensor 111 can be connected to and/or communicate with the control unit 90. Furthermore, the radiator 120 can be controlled and/or regulated via the control unit 90 in order to set the testing temperature of the sampler stage 110. In a moderate temperature range around room temperature, the testing temperature can be regulated by a controlled regulation of both the radiator 120 and the temperature regulation in the temperature-regulating apparatus 1.

The aforementioned temperature ranges are valid at least when the introduced temperature-regulating fluid has a provisional temperature around room temperature. If the introduced temperature-regulating fluid is provided with a greatly deviating temperature, then the temperature regulation is performed with a combination of cold and heat in a range around the provisional temperature, solely with the radiator 120 in a temperature range significantly above this, and solely with the coldness of the temperature-regulating fluid in a temperature range significantly below this.

Specifically when regulating the sampler stage 110 to lower temperatures, i.e., for example, when setting testing temperatures in the negative Celsius range, it can be sensible in terms of energy to use a temperature-regulating fluid fed back from the sampler stage 110 for the temperature pre-regulation of the fresh temperature-regulating fluid in the second heat exchanger 30. The temperature-regulating fluid used for the temperature regulation in the sampler stage 110 can be fed back from the sampler stage 110 via a feedback line 50 into a feedback inlet 51 of the temperature-regulating apparatus 1. From the feedback inlet 51, it can be conducted via a feedback circuit inlet line 52 into the feedback circuit 60 of the temperature-regulating apparatus 1. The feedback circuit 60 can be controlled and/or regulated by the control unit 90. For this purpose, the control unit 90 can provide and/or generate a feedback switch signal, with which the feedback circuit 60 can be reversibly switched between at least two states. Depending on the switch position of the feedback circuit 60, the temperature-regulating apparatus 1 is either in a feedback operating state or in an outflow operating state.

In the outflow operating state, the fed back temperature-regulating fluid is conducted via a second outflow line 65 to a second outflow outlet 62, where it is allowed to flow out. At the second outflow outlet 62, a sound damper and/or at least one outflow valve can be arranged, for example, in order to discharge the temperature-regulating fluid as noiselessly and/or as safely as possible into the environment. In the outflow operating state, the hot and cold energy of the fed back temperature-regulating fluid is not used for the temperature pre-regulation of the freshly introduced temperature-regulating fluid.

In the feedback operating state, the fed back temperature-regulating fluid is conducted by the feedback circuit via a heat exchanger feedback line 63 through the first heat exchanger 20. In the first heat exchanger 20, a heat exchange can occur between the fed back temperature-regulating fluid and the temperature-regulating fluid freshly introduced through the fluid inlet 10, wherein a temperature pre-regulation takes place.

After passing through the first heat exchanger 20, the fed back temperature-regulating fluid can be conducted to a first outflow outlet 61 via a first outflow line 64. The first outflow outlet 61 can also be configured similar to the second outflow outlet 62, i.e. having a sound damper and/or outflow valve(s).

For this purpose, the temperature-regulating apparatus 1 can be configured so as to enter into the feedback operating state when the sampler stage 110 is to be set to a comparatively low testing temperature. This can be the case, for example, for testing temperatures in a range from a minimum adjustable temperature up to a range around room temperature or just below room temperature. If the sampler stage 110 is to be cooled to a testing temperature of −40° C., for example, then the temperature-regulating fluid conducted to the sampler stage 110 via the sampler temperature-regulating line 40 can be temperature-regulated to an approximate target temperature of −40° C. The temperature-regulating fluid fed back via the feedback line 50 can still have a temperature of, for example, approximately −30° C., so that it can be well used in the first heat exchanger 20 for the temperature pre-regulation of the fresh temperature-regulating fluid introduced at approximately room temperature. As a result, the freshly introduced temperature-regulating fluid is pre-cooled in the first heat exchanger 20, before it is completely cooled down to a target temperature of −40° C. degrees Celsius in the second heat exchanger 30 via a cooling capacity of the cooling apparatus 35.

However, in other operating states, the use of the fed back temperature-regulating fluid can be counterproductive. If, for example, the sampler stage 110 is to be cooled down from a current testing temperature of, for example, 300° C. to a new testing temperature in the negative range and/or close to room temperature, then the use of the very hot fed back temperature-regulating fluid in the first heat exchanger 20 would be counterproductive when cooling off the sampler stage 110. During the cooling, in particular when setting a testing temperature which is at least approximately 50K lower than the previously used testing temperature, the temperature-regulating apparatus 1 can be put into the outflow operating state. In this state, the fed back temperature-regulating fluid can no longer be conducted through the first heat exchanger 20, but rather is allowed to flow out via the second outflow outlet 62 while bypassing the first heat exchanger 20. In the outflow operating state, the sampler stage 110 can thus be cooled down significantly faster to the new testing temperature to be set while expending less cooling capacity.

FIG. 2 shows a schematic outline of a further exemplary embodiment of the sampler system having a temperature-regulating apparatus 1 and a sampler container 100. In the exemplary embodiment shown in FIG. 2, the same or similar components and/or features bear the same reference numerals as in FIG. 1.

Like the sampler system described in FIG. 1, the sampler system shown in FIG. 2 also comprises a temperature-regulating apparatus 1 and the sampler container 100 with the sampler stage 110. The sampler system shown in FIG. 2 comprises a temperature-regulating apparatus 1, in which an inlet fluid circuit 80 is integrated. The freshly introduced temperature-regulating fluid is conducted from the fluid inlet 10 via vet inlet line 11 to the inlet fluid circuit 80. The inlet fluid circuit 80 can be switched between at least two states. Here, the inlet fluid circuit 80 can be switched into either a heat exchanger mode or a booster mode, for example in response to an introduction switch signal provided by the control unit 90.

If the inlet fluid circuit 80 is switched into the heat exchanger mode, then the introduced temperature-regulating fluid is conducted from the inlet fluid circuit 80 via a heat exchanger inlet line 11w to the heat exchanger 30. In the heat exchanger 30, the temperature-regulating fluid is temperature-regulated, for example by the cooling apparatus 35, and subsequently conducted to the sampler temperature-regulating line 40 through a heat exchanger outlet line 31 and, for example, a convergence 42. The convergence 42 can be configured, for example, as an “OR”/shuttle valve.

Although only a single heat exchanger 30 is shown in FIG. 2, the introduced temperature-regulating fluid can also pass through more than one heat exchanger in the heat exchanger mode.

As an alternative to the heat exchanger mode, the inlet fluid circuit can also switch the temperature-regulating apparatus 1 into a booster mode. In the booster mode, the freshly introduced temperature-regulating fluid is not conducted through the heat exchanger 30, but rather via a booster inlet line 11b to a cooling booster 70. In the cooling booster 70, the temperature-regulating fluid is temperature-regulated and subsequently conducted via a booster outlet line 71 to the convergence 42 and from there to the fluid outlet 41 and/or to the sampler temperature-regulating line 40. At the convergence 42, the outlet lines 31 and 71 from the heat exchanger 30 and the cooling booster 70 are combined and, from there, further conducted to the fluid outlet 41 and/or to the sampler temperature-regulating line 40. The convergence, which can be configured for example as an “OR” valve, can prevent an undesired fluid flow to the cooling booster 70 in the heat exchanger mode and can prevent an undesired fluid flow to the heat exchanger 30 in the booster mode.

The cooling booster 70 can be based on the principle of the vortex tube. In the vortex tube, the temperature-regulating fluid is separated into a warm portion and a cold portion as a result of the swirling. The warm portion of the temperature-regulating fluid can be allowed to flow out via a booster outflow line 73 and a booster outflow outlet 72. The cold portion of the temperature-regulating fluid can be further used for the temperature regulation of the sampler stage 110.

The cooling booster 70 shown can use less operational energy than the cooling apparatus 35. For this reason, when circumstances allow, the cooling booster 70 is preferably used for cooling, and not the cooling apparatus 35 with the heat exchanger 30.

In one embodiment, the temperature-regulating apparatus can be operated at temperatures in the negative Celsius range in the heat exchanger mode, in particular up to a temperature just below room temperature.

In a temperature range around room temperature, the temperature-regulating apparatus 1 can be operated in the booster mode. The temperature range around room temperature can be regulated solely by means of the cooling booster 70. In a range significantly above room temperature, the sampler stage 110 can be temperature-regulated solely by the radiator 120.

For example, in a range from the minimum adjustable testing temperature (e.g. −40° C. or −55° C.) up to the lower threshold temperature (e.g. approximately +15° C.), the temperature-regulating apparatus 1 can normally be operated in the heat exchanger mode. At testing temperatures from the lower threshold temperature (e.g. approximately 15° C.) up to the upper threshold temperature (e.g. approximately 60° C. or approximately 50° C.), the temperature-regulating apparatus 1 can be operated in the booster mode. At warmer testing temperatures, the temperature-regulating apparatus 1 can largely be switched off, and the temperature of the sampler stage 110 can be set by means of the radiator 120.

FIG. 3 shows a schematic outline of a sampler system having a temperature-regulating apparatus 1 and a sampler container 100, which unifies and combines the advantages of the two sampler systems shown in FIG. 1 and FIG. 2. This can lead to a particularly energy-efficient and/or noiseless operation of the temperature-regulating apparatus, which can quickly set various testing temperatures.

The reference numerals used in FIG. 3 refer to features that have already been described with respect to the exemplary embodiments shown in FIG. 1 and FIG. 2. Thus, the sampler system shown in FIG. 3 can be operated in various operating states.

The temperature-regulating apparatus 1 can be operated in the booster mode as well as in the heat exchanger mode. For this purpose, it comprises the inlet fluid circuit 80, which conducts the freshly introduced temperature-regulating fluid to the sampler temperature-regulating line 40 either through the cooling booster 70 or the first heat exchanger 20 and the second heat exchanger 30. In the booster mode, the cooling apparatus 1 can be switched off, turned down, and/or placed into standby mode.

As an alternative to the booster mode, the temperature-regulating apparatus 1 can be operated in the heat exchanger mode. In the heat exchanger mode, the temperature-regulating apparatus 1 can either be operated in the outflow operating state or in the feedback operating state. These operating states are controlled and/or regulated via the control unit 90 and the feedback circuit 60. If the feedback circuit 60 conducts the fed back temperature-regulating fluid through the first heat exchanger 20, it can be used there for the temperature pre-regulation of the freshly introduced temperature-regulating fluid. If the feedback circuit 60 conducts the fed back temperature-regulating fluid around the first heat exchanger 20, then the freshly introduced temperature-regulating fluid flows through the first heat exchanger 20 substantially without a temperature change and is temperature-regulated exclusively in the second heat exchanger 30.

In a heating operating state, both the cooling apparatus 35 and the cooling booster 70 can be switched off and/or placed into standby mode.

Due to the various operating states and operating modes, the embodiment shown in FIG. 3 is particularly energy-efficient and sparing and reduces the operating noise.

FIG. 4 shows a schematic outline of an exemplary embodiment of a sampler system having a temperature-regulating apparatus, of which at least components are shown in FIG. 4, and a sampler stage. FIG. 4 shows an exemplary embodiment that is the same as the one shown in FIG. 3, but to a different degree of detail.

As in the exemplary embodiment shown in FIG. 3, the sampler system can comprise a fluid inlet, through which freshly introduced temperature-regulating fluid can be conducted. The freshly introduced temperature-regulating fluid is conducted [by] the control unit 90 [through] a proportional valve V1. Alternatively, the freshly introduced temperature-regulating fluid can also be conducted through a switch valve V5, which can be configured as a discharge and/or sound damper valve. In the proportional valve V1, it can be adjusted how much temperature-regulating fluid is to be used for the temperature regulation.

Depending on the operating state and the switch positions of the proportional valve V1 and/or the switch valve V5, a component of the freshly introduced temperature-regulating fluid can also be allowed to directly flow out while bypassing the heat exchangers 20, 30 and the cooling booster 70, either via a sound damper valve V3 and the first outflow outlet 61 and/or via a discharge valve V4 and the second outflow outlet 62.

From the proportional valve V1, the temperature-regulating fluid is conducted through a switch valve V2, which can be configured as a component of the inlet fluid circuit 80. Depending on the switch position of the inlet fluid circuit 80, the temperature-regulating apparatus 1 is either in the booster mode or in the heat exchanger mode.

### Booster Mode, e.g. in the Moderate Temperature Range

In the booster mode, the temperature-regulating fluid is conducted from the switch valve V2 through the cooling booster 70 and temperature-regulated there. From there, the warm portion of the temperature-regulating fluid is conducted out via the booster outflow outlet 72, while the cold portion is conducted into the sampler temperature-regulating line 40 via a convergence 42. The convergence 42 can comprise a shuttle valve and/or an “OR” valve.

In the booster mode, the introduced temperature-regulating fluid is conducted to the sampler stage 110 via the cooling booster 70. The booster mode can be used, for example, when the sampler stage 110 is to be conditioned to a testing temperature in a moderate temperature range, for example a temperature range from a lower threshold temperature up to an upper threshold temperature. This moderate temperature range can include the room temperature and/or the provisional temperature at which the freshly introduced temperature-regulating fluid is provided. In one exemplary embodiment, the lower threshold temperature is approximately 10° C. to approximately 25° C., for example approximately 15° C. In one exemplary environment, the upper threshold temperature is approximately 40° C. to approximately 80° C., preferably approximately 50° C. to approximately 70° C., particularly preferably approximately 60° C.

In the booster mode, the proportional valve V1 is opened so that the fresh temperature-regulating fluid can flow through the proportional valve V1. Furthermore, the switch valve V2 is opened such that the temperature-regulating fluid is conducted to the cooling booster 70. The switch valve V5 is also opened in order to be able to divert any excess temperature-regulating fluid. The discharge valve V4 can be closed, and the sound damper valve V3 can be opened, so that the fed back temperature-regulating fluid can flow out through the first heat exchanger 20 and the sound damper valve 20 (feedback operating state) without temperature pre-regulating the freshly introduced temperature-regulating fluid, because it does not pass through the first heat exchanger 20 at all in the booster mode. Alternatively, the discharge valve V3 can be opened (outflow operating state) in order to allow the fed back temperature-regulating fluid to flow out through the discharge valve V3 and the second outflow outlet 62. In the booster mode, the cooling apparatus 35 can be switched off and/or operated in standby mode.

### Heat Exchanger Mode

In the heat exchanger mode, the introduced temperature-regulating fluid is conducted from the switch valve V2 into the first heat exchanger 20 and from there into the second heat exchanger 30. In the second heat exchanger 30, the temperature-regulating fluid is temperature-regulated by the cooling apparatus as a coldness stage and subsequently conducted to the convergence 42. From there, it is conducted further through the sampler temperature-regulating line 40 to the sampler stage 110.

From the sampler stage 110, the temperature-regulating fluid already used there for the temperature regulation is brought into the feedback line 50 and conducted back to the temperature-regulating apparatus. In doing so, the fed back temperature-regulating fluid passes a bifurcation 60′, which can be configured as a component of the feedback circuit 60. The feedback circuit 60 comprises a discharge valve V4, via which the fed back temperature-regulating fluid can be allowed to flow out in the second outflow outlet 62 while bypassing the first heat exchanger. Depending on the switch position of the discharge valve V4, the temperature-regulating apparatus is either in the outflow operating state or the feedback operating state.

### Feedback Operating State, e.g. in a Low Temperature Range

In the heat exchanger mode and the feedback operating state, the inlet fluid circuit 80 is switched to the heat exchanger mode, and the feedback circuit 60 is switched to the feedback operating state. Such an operation of the temperature-regulating apparatus can be used sensibly, in particular, when a significant cooling of the sampler stage 110 is required. This can be the case when a testing temperature is to be set, for example, in a low temperature range, i.e., for example, a testing temperature between the minimum adjustable temperature, for example −40° C. or −60° C., up to a previously described lower threshold temperature of the moderate temperature range.

In the heat exchanger mode and the feedback operating state, the proportional valve V1 and the switch valve V2 are opened. Furthermore, the switch valve V5 is also opened and the discharge valve V4 is also closed. This forces the fed back temperature-regulating fluid through the first heat exchanger 20, after which it can flow through an opened sound damper valve V3 to the first outflow outlet 61. The fed back temperature-regulating fluid is conducted into the first heat exchanger 20, where it can temperature pre-regulate the freshly introduced temperature-regulating fluid in order to not waste its coldness content, but rather to further utilize it.

### Outflow Operating State, e.g. When Cooling the Sampler Stage

In a heat exchanger mode and outflow operating state, the temperature-regulating apparatus can be used in order to cool off the sampler stage 110 from a high temperature. This combination of operating modes and states is sensible, for example, when the sampler stage 110 is to be cooled off from a high first temperature (for example, a temperature in the range of approximately 100° C. to to 400° C.) to a significantly lower second temperature, for example a second temperature that is at least 50K lower than the first temperature, particular at least 100K lower. The second temperature can be, for example, in the range from the minimum adjustable temperature to the upper threshold temperature.

The inlet fluid circuit 80 is switched to the heat exchanger mode, and the feedback circuit 60 is switched to the outflow operating state. This can be realized in that the proportional valve V1 is opened and the switch valve V2 is opened in such a way that no introduced temperature-regulating fluid is conducted to the first heat exchanger. The switch valve V5 is closed and the discharge valve V4 is opened, while the sound damper valve V3 is closed. The closed position of the sound damper valve V3 causes a backlog so that the temperature-regulating fluid fed back via the feedback line 50 can no longer be conducted through the first heat exchanger 20. Rather, it flows out through the discharge valve V4 via the second outflow outlet 62. Thus, the freshly introduced temperature-regulating fluid can be temperature-regulated and cooled down alone in the second heat exchanger 30 without the hot fed back temperature-regulating fluid causing an inefficient and unfavorable temperature pre-regulation in the first heat exchanger 20.

### Heating Operating State

In the heating operating state, both the cooling booster 70 and the cooling apparatus 35 can be switched off or placed into standby mode, and the temperature of the sampler stage 110 can be conditioned solely by a radiator 120 (not shown in FIG. 4). In particular, the heating mode can be used in a temperature range above the upper threshold temperature, i.e., for example, a temperature range from the upper threshold temperature to the maximum adjustable temperature of the sampler stage 110.

In an alternative embodiment not shown in the figures, the inlet circuit is arranged between the first heat exchanger and the second heat exchanger. Thus, the feedback and the temperature pre-regulation by means of the fed back temperature-regulating fluid can be used in the heat exchanger mode as well as in the booster mode. The remaining construction of this temperature-regulating apparatus and/or this sampler system can be configured analogously to the embodiments shown in FIG. 3 and/or FIG. 4.

With the sampler system and/or the temperature-regulating apparatus, a particularly efficient energy usage is enabled, as well as a rapid switching and setting of a changed testing temperature of the sampler stage 110. Furthermore, operating noise can be reduced.

### LIST OF REFERENCE NUMERALS

1 Temperature-regulating apparatus
10 Fluid inlet
11 Inlet line
11b Booster inlet line
11w Heat exchanger inlet line
20 First heat exchanger
21 Heat exchanger connection line
30 Second heat exchanger
31 Heat exchanger outlet line
35 Cooling apparatus
40 Sampler temperature-regulating line
41 Fluid outlet
42 Convergence
50 Feedback line
51 Feedback inlet
52 Feedback circuit inlet line
60 Feedback circuit
60′ Bifurcation
61 First outflow outlet
62 Second outflow outlet
63 Heat exchanger feedback line
64 First outflow line
65 Second outflow line
70 Cooling booster
71 Booster outlet line
72 Booster outflow outlet
73 Booster outflow line
80 Inlet fluid circuit
90 Control unit
100 Sampler container
110 Sampler stage
111 Temperature sensor
120 Radiator
V1 Proportional valve
V2 Switch valve
V3 Sound damper valve
V4 Discharge valve
V5 Switch valve

1. A temperature-regulating apparatus (1) for temperature regulation of a sampler stage (110) for semiconductor wafers and/or hybrids, having
a fluid inlet (10) for introducing a temperature-regulating fluid into the temperature-regulating apparatus (1);
a first heat exchanger (20) for temperature pre-regulation of the introduced temperature-regulating fluid;
a second heat exchanger (30) for temperature regulation of the temperature-regulating fluid;
a sampler temperature-regulating line (40) through which the temperature-regulated temperature-regulating fluid can be conducted to the sampler stage (110); and
a feedback circuit (60), which, in response to a feedback switch signal, optionally either conducts a temperature-regulating fluid fed back from the sampler stage (110) through the first heat exchanger (20) or allows it to flow out while bypassing the first heat exchanger (20).

2. The temperature-regulating apparatus (1) according to claim 1, wherein, in a feedback operating state of the temperature-regulating apparatus (1), the fed back temperature-regulating fluid temperature pre-regulates the introduced temperature-regulating fluid in the first heat exchanger (20) when it is conducted by the feedback circuit (60) through the first heat exchanger (20).

3. The temperature-regulating apparatus (1) according to claim 1 or 2, wherein, after flowing through the first heat exchanger (20), the fed back temperature-regulating fluid is allowed to flow out via an outflow outlet (61).

4. The temperature-regulating apparatus (1) according to any one of the preceding claims, wherein, in an outflow operating state of the temperature-regulating apparatus (1), the feedback circuit (60) allows the temperature-regulating fluid fed back from the sampler stage (110) to flow out while bypassing the first heat exchanger (20) when the sampler stage (110) is cooled off from a heated state.

5. The temperature-regulating apparatus (1) according to any one of the preceding claims, wherein, upon cooling of the sampler stage (110) in an outflow operating state of the temperature-regulating apparatus (1), the feedback circuit (60) allows the temperature-regulating fluid fed back from the sampler stage (110) to flow out while bypassing the first heat exchanger (20) until a temperature of the sampler stage (110) falls below a sampler stage threshold temperature within a range of approximately 20° C. to approximately 40° C.

6. The temperature-regulating apparatus (1) according to any one of the preceding claims, wherein, in a feedback operating state of the temperature-regulating apparatus (1), the feedback circuit (60) conducts the temperature-regulating fluid fed back from the sampler stage (110) through the first heat exchanger (20) when the sampler stage (110) is temperature-regulated to a temperature below a feedback threshold temperature.

7. The temperature-regulating apparatus (1) for temperature-regulating a sampler stage (110) for semiconductor wafers and/or hybrids, in particular according to any one of the preceding claims, having
a fluid inlet (10) for introducing a temperature-regulating fluid into the temperature-regulating apparatus (1);
at least one heat exchanger (20; 30) for temperature regulation of the temperature-regulating fluid;
a cooling booster (70) for temperature regulation of the temperature-regulating fluid;
a sampler temperature-regulating line (40), through which the temperature-regulated temperature-regulating fluid can be conducted to the sampler stage (110); and
an inlet fluid circuit (80), which, in response to an introduction switch signal, optionally conducts the introduced temperature-regulating fluid into the sampler temperature-regulating line (40) either through the at least one heat exchanger (20; 30) or through the cooling booster (70).

8. The temperature-regulating apparatus (1) according to claim 7, wherein, in a heat exchanger mode of the temperature-regulating apparatus (1), the inlet fluid circuit (80) conducts the introduced temperature-regulating fluid through the at least one heat exchanger (20; 30) into the sampler temperature-regulating line (40) when the sampler stage (110) is cooled off from a heated state.

9. The temperature-regulating apparatus (1) according to claim 7 or 8, wherein, in a heat exchanger mode of the temperature-regulating apparatus (1), the inlet fluid circuit (80) conducts the introduced temperature-regulating fluid through the at least one heat exchanger (20; 30) into the sampler temperature-regulating line (40) when the sampler stage (110) is temperature-regulated to a temperature below a lower threshold temperature lying within a range of approximately 10° C. to approximately 25° C.

10. The temperature-regulating apparatus (1) according to claim 7 or 9, wherein, in a booster mode of the temperature-regulating apparatus (1), the inlet fluid circuit (80) conducts the introduced temperature-regulating fluid through the cooler booster (70) into the sampler temperature-regulating line (40) when the sampler stage (110) is temperature-regulated to a temperature above an upper threshold temperature lying within a range of approximately 10° C. to approximately 25° C. and below a lower threshold temperature lying within a range of approximately 40° C. to approximately 70° C.

11. The temperature-regulating apparatus (1) according to any one of claims 7 to 10, wherein the cooling booster (70) comprises a vortex tube in which the introduced temperature-regulating fluid is divided into a warm and a cold flow portion, of which only the cold flow portion is conducted into the sampler temperature-regulating line (40).

12. The temperature-regulating apparatus (1) according to any one of claims 7 to 11, wherein the inlet fluid circuit (80) comprises a switch valve through which the introduced temperature-regulating fluid is optionally conducted to either the at least one heat exchanger (20; 30) or the cooling booster (70) as a function of the switch position of the switch valve.

13. A system having a sampler stage (110) and a temperature-regulating apparatus (1) according to any one of the preceding claims connected thereto at least via its sampler temperature-regulating line (40).

14. A method for temperature regulation of a sampler stage (110) for semiconductor wafers and/or hybrids, having the following steps:
introducing a temperature-regulating fluid into a first heat exchanger (20) for temperature pre-regulation of the introduced temperature-regulating fluid;
conducting the temperature-regulating fluid from the first heat exchanger (20) into a second heat exchanger (30) for temperature regulation of the temperature-regulating fluid;
conducting the temperature-regulated temperature-regulating fluid to the sampler stage (110); and
providing a feedback switch signal for controlling and/or adjusting a feedback circuit (60), wherein, in response to a feedback switch signal, a temperature-regulating fluid fed back from the sampler stage (110) is optionally either conducted through the first heat exchanger (20) or is allowed to flow out while bypassing the first heat exchanger (20).

15. The method according to claim 14, having at least one of the following steps:
allowing the outflow of the temperature-regulating fluid fed back from the sampler stage (110) while bypassing the first heat exchanger (20) when the sampler stage (110) is cooled off from a heated state; and/or
conducting the temperature-regulating fluid fed back from the sampler stage (110) through the first heat exchanger (20) when the sampler stage (110) is temperature-regulated to a temperature below a feedback threshold temperature.

16. The method for temperature regulation of a sampler stage (110) for semiconductor wafers and/or hybrids, in particular according to any one of claim 14 or 15, having the following steps:
introducing a temperature-regulating fluid into at least one heat exchanger (20; 30) for temperature regulation of the temperature-regulating fluid;
introducing the temperature-regulating fluid into a cooling booster (70) for temperature regulation of the temperature-regulating fluid;
conducting the temperature-regulated temperature-regulating fluid to the sampler stage (110); and
providing an introduction switch signal for controlling and/or adjusting an inlet fluid circuit (80), wherein, in response to an introduction switch signal, the introduced temperature-regulating fluid is optionally conducted to the sampler stage (110) either through the at least one heat exchanger (20; 30) or through the cooling booster (70).

17. The method according to claim 16, having at least one of the following steps:
conducting the introduced temperature-regulating fluid through the at least one heat exchanger (20; 30) to the sampler stage (110) when the sampler stage (110) is temperature-regulated to a temperature below a lower threshold temperature lying within a range of approximately 10° C. to approximately 25° C.;
conducting the introduced temperature-regulating fluid through the cooler booster (70) to the sampler stage (110) when the sampler stage (110) is temperature-regulated to a temperature above an upper threshold temperature lying within a range of approximately 10° C. to approximately 25° C. and below a lower threshold temperature lying within a range of approximately 40° C. to approximately 70° C.;
switching off a cooling apparatus (35) used for temperature regulation within the heat exchanger (20; 30) when the introduced temperature-regulating fluid is conducted through the cooling booster (70) to the sampler stage (110); and/or
switching off a cooling apparatus (35) used for temperature regulation within the heat exchanger (20; 30) and/or switching off the cooling booster (70) when the sampler stage (110) is temperature-regulated to a temperature above the upper threshold temperature lying within a range of approximately 40° C. to approximately 70° C.
